(19) United States
(12) Patent Application Publication
(10) Pub. No.: US 2023/0012109 A1
(43) Pub. Date: Jan. 12, 2023

(54) OVER-VOLTAGE PROTECTION CIRCUITRY

(71) Applicant: VISIC TECHNOLOGIES LTD, Ness Ziona (IL)

(72) Inventors: David SHAPIRO, Rishon LeZion (IL); Shmuel BEN YAAKOV, Tel Yitzhak (IL); Evgeny ROSANOV, Rishon LeZion (IL); Yuri GITELMAKHER, Beer Sheva (IL); Ilia BUNIN, Holon (IL)

(21) Appl. No.: 17/783,799

(22) PCT Filed: Dec. 15, 2020
(86) PCT No.: PCT/IL2020/051288

§ 371 Date: Jun. 9, 2022

(30) Foreign Application Priority Data
Dec. 15, 2019 (IL) 271448

(51) Int. Cl. H02M 1/34; H02M 7/537; H03K 17/0814

(52) U.S. Cl. CPC H02M 1/348; H02M 7/537; H03K 17/08142

(57) ABSTRACT

Circuitry for reducing the energy losses of a snubber circuit used to protect current switching devices from overvoltage, comprising a switching cell consisting of a switch with alternating opposite conduction states, the switch being serially connected via one contact to a first diode, the switch includes an inherent output capacitance, the switch connects, via a first stray inductance), between one port of a power supply and an output inductor feeding a load, and the first diode connects, via a second stray inductance, between the other port of the power supply and the output inductor, such that whenever the switch passes from a conducting state to a non-conducting state, its inherent output capacitance is charged by a current pulse from the first stray inductance; a snubber circuit consisting of a ferrite bead, a snubber capacitor and a second diode, the snubber circuit being connecting between the other contact of the switch and the other port, for discharging at least a portion of the charge across the inherent output capacitance of the switch to the snubber capacitor via the other port.

### FIELD OF THE INVENTION

The present invention relates to the field of overvoltage protection circuitry. More particularly, the invention relates to circuitry and method for protecting sensitive transistors such as GaN HEMT (Gallium Nitride High-Electron-Mobility Transistor) from overvoltage, with reduced energy losses.

### BACKGROUND OF THE INVENTION

A snubber is a device used to suppress (“snub”) voltage transients in electrical systems. Snubbers are frequently used in electrical systems with an inductive load where the sudden interruption of current flow leads to a sharp rise in voltage across the current switching device. This transient can be a source of electromagnetic interference (EMI) in other circuits. Additionally, if the voltage generated across the device is beyond what the device is intended to tolerate, it may damage or destroy it. The snubber provides a short-term alternative current path around the current switching device so that the inductive element may be safely discharged.

MOSFET transistors, and in particular the faster Gallium Nitride (GaN) transistors which are used in converters as a current switching device, are very sensitive to overvoltage, and tend to burn easily if they are not properly protected.

Today, MOSFET transistors are used for high-frequency and high-power circuits. When the transistor is off and no current is flowing, the voltage rises, and when the voltage rises above a certain threshold, the transistor may be burned. FIG. 1 (prior art) shows the transient response of VDS of a transistor, following switching from conduction to cutoff.

Today, a common use of MOSFET transistors is for implementing a “half bridge”, as shown in FIG. 2 (prior art). “Half a bridge” uses two transistors Q1 and Q2. Because each transistor is a kind of a “chip”, it is packed in a package with external ports (“legs”), for connection to a PCB and/or to other components. Connections to the chip are made using thin bond wires, each of which will have some inductance L_{S}. The thinner, the finer and the longer the wire, the higher is its inductance. Furthermore, the interconnection of the MOSFET transistor to each other and of the transistors to the bus line also have a stray inductance. When the transistor stops conducting, the current in the stray inductances stops flowing abruptly, causing a high voltage Vpk to develop across the drain-source due to the relationship:

$$V = L \frac{dI}{dt} \qquad ( 1 )$$

Where V is the voltage developed L is the inductance and dl/dt is the rate at which the current is changing. FET transistors such as GaN MOSFETS have a very fast turn-off time and hence dl/dt would be very high. In particular, which a transistor is turned off, say Q1 in FIG. 2 the current through the transistor is quickly turned off and the current via Ls1 is bypassed to the transistor's output capacitor Coss1.

The serial connection of Ls1 and Coss1 forms a resonance circuit with an initial high current that results in overshoot and may cause the transistor to burn. The maximum value can be approximated by the relationship

Ls1·Iₒ²=Coss1·V_{cmax}² (2)

where Io is the initial current and Vcmax is the added voltage on the transistor. Or

$${V}_{cmax}^{2} = {I}_{o} \sqrt{\frac{Ls 1}{Coss 1}} \qquad ( 3 )$$

It is thus evident that the combination of a fast transistor which turns off abruptly and the resonant effect of the stray inductance and output capacitance of the transistor may generate a high voltage that may destroy the transistor. This is very well known in the art.

A common way to solve the problem is illustrated in FIG. 3A (prior art). The high voltage is chopped by adding a capacitor Csn with a high capacitance that can absorb the energy. When Q1 is in cutoff, the current I_{LS} cannot flow through the transistor Q1 and instead, flows through the capacitor Csn which is being charged. If Csn is sufficiently large, it absorbs the energy and the overshoot in voltage V_{DS} is eliminated (per equation 3 above, in which Coss1 is now in parallel with a very large capacitor), as shown in FIG. 3B (prior art). However, when the capacitor Csn is charged, the next time it will be charged further and the next time it will be even more charged, so the voltage V_{c}_{ₛₙ} across it continues to rise, until the capacitor Csn must be discharged.

There are two methods to discharge the capacitor:

In the first method, the capacitor is completely discharged. This method is problematic because there is a large amount of energy that needs to be discharged and charged again and again. This causes additional power losses due to the circulating current.

In the second method demonstrated here by a half-bridge configuration, there are two transistors, an upper transistor Q1 and a lower transistor Q2, as shown in FIG. 3C. When the upper transistor Q1 conducts and the current through it continues to the lower transistor. When the upper transistor Q1 is turned off, the current through Ls1 continues to the output capacitor Csn1 and charges it via D1, and then Csn1 discharges to ground via resistor Rsn1. This process is repeated, while each time Csn1 is charged and discharges. Since the capacitor Csn1 needs to be discharged rapidly, a small resistor Rsn1 is used and thus the time constant will be small.

However, the problem with this method is the loss of energy when discharging the capacitor, regardless the value of resistor Rsn1. Half of the energy is lost when the capacitor is discharged. When a capacitor is being charged or discharged via an energy source, the total energy is CV², half of which is lost and wasted on the resistor Rsn1. When the resistor Rsn1 is large, there is a small current, but the process takes a longer time, and when the resistor is small, there is a very large current, but the process takes short time. So the total energy that is being lost is the same, half the amount of energy (½ CV²).

Another problem with conventional solutions is the problem of heat dissipation of the energy consumed by the discharge resistor. Depending on the power level of the converter, the dissipated power may reach tens of Watts, and hence, the discharge resistor must be physically large, in order to prevent overheating.

FIG. 3D (prior art) illustrates another circuitry for solving this type of problem, using a coil and a diode to reduce the energy losses. In this solution, when switch S1 stops conducting, capacitor C1 is charged and then discharges through a series connection of a coil L1 and a diode D12, in order to reduce losses. D12 is used for preventing oscillations, since there is no damping element in the discharge path. The drawback of this solution is that it is relatively expensive since the two elements, need to carry a high peak current. Furthermore, since the inductor and capacitor form a resonant network, high-frequency oscillation will be occurring generating undesired Electro Magnetic Interference (EMI) and increasing the RMS current and hence the losses.

When the current contains a lot of high-frequency components, the energy losses are larger. The smoother the current and the closer to DC, the ratio between the average and RMS values will be equal to 1 and consequently, the losses of energy will be smaller. By using a coil L1 and a diode D12, one can reduce the RMS current and thereby reduce the energy losses. However, the disadvantage of this method is that it is necessary to use the coil, which is physically large, even if its inductance is small and needs to withstand a high peak current. Also, the diode should be fast since a slow reverse recovery will cause oscillations and additional EMI. Also, such an implementation is expensive.

It is therefore an object of the present invention to provide a protection circuitry for protecting a transistor from overvoltage, which is cheap and easy to implement.

It is another object of the present invention to reduce the energy loss on protection circuitry.

Other objects and advantages of the invention will become apparent as the description proceeds.

### SUMMARY OF THE INVENTION

A method for reducing the energy losses of a snubber circuit used to protect current switching devices from overvoltage, comprising the steps of:
a) providing a switching cell consisting of a switch with alternating opposite conduction states, the switch being serially connected via one contact to a first diode, the switch includes an inherent output capacitance, the switch connects, via a first stray inductance, between one port of a power supply and an output inductor feeding a load, and the first diode connects, via a second stray inductance, between the other port of the power supply and the output inductor, such that whenever the switch passes from a conducting state to a non-conducting state, its inherent output capacitance is charged by a current pulse from the first stray inductance; and
b) connecting a snubber circuit consisting of a ferrite bead, a snubber capacitor and a second diode, between the other contact of the switch and the other port, for discharging at least a portion of the charge across the inherent output capacitance of the switch to the snubber capacitor via the other port.

The ferrite bead may be represented by a parallel connection of a stray capacitor, a frequency-dependent inductor and a frequency-dependent resistor, the parallel connection is followed by a series of constant resistance.

In one aspect, the ferrite bead smooths the discharge current of the output capacitance.

The peak resistance of the frequency-dependent resistor may be in the range of 1 to 10 KΩ.

The switch may be implemented by a FET transistor or a power GaN transistor.

Circuitry for reducing the energy losses of a snubber circuit used to protect current switching devices from overvoltage, comprising:
a. a switching cell consisting of a switch with alternating opposite conduction states, the switch being serially connected via one contact to a first diode, the switch includes an inherent output capacitance, the switch connects, via a first stray inductance, between one port of a power supply and an output inductor feeding a load, and the first diode connects, via a second stray inductance), between the other port of the power supply and the output inductor, such that whenever the switch passes from a conducting state to a non-conducting state, its inherent output capacitance is charged by a current pulse from the first stray inductance; and
b. a snubber circuit consisting of a ferrite bead, a snubber capacitor and a second diode, the snubber circuit being connecting between the other contact of the switch and the other port, for discharging at least a portion of the charge across the inherent output capacitance of the switch to the snubber capacitor via the other port.

A half bridge circuitry for reducing the energy losses of a snubber circuit used to protect current switching devices from overvoltage, comprising:
a. a first switching cell consisting of a first switch with alternating opposite conduction states, the switch being serially connected via one contact to a first diode, the first switch includes an inherent output capacitance, the first switch connects, via a first stray inductance, between one port of a power supply and an output inductor feeding a load, and the first diode connects, via a second stray inductance, between the other port of the power supply and the output inductor, such that whenever the switch passes from a conducting state to a non-conducting state, its inherent output capacitance is charged by a current pulse from the first stray inductance;
b. a second switching cell consisting of a second switch with alternating opposite conduction states, the second switch being serially connected via one contact to a third diode, the second switch includes an inherent output capacitance, the second switch connects, via a third stray inductance, between one port of the power supply and an output inductor feeding the load, and the third diode connects, via a fourth stray inductance, between the other port of the power supply and the output inductor, such that whenever the second switch passes from a conducting state to a non-conducting state, its inherent output capacitance is charged by a current pulse from the third stray inductance;
c. a first snubber circuit consisting of a ferrite bead, a snubber capacitor and a second diode, the first snubber circuit being connecting between the other contact of the first switch and the other port, for discharging at least a portion of the charge across the inherent output capacitance of the first switch to the snubber capacitor via the other port; and
d. a second snubber circuit consisting of a ferrite bead, a snubber capacitor and a second diode, the second snubber circuit being connecting between the other contact of the second switch and the other port, for discharging at least a portion of the charge across the inherent output capacitance of the first switch to the snubber capacitor via the other port.

The first and second switches may be FET transistors or GaN transistors.

### BRIEF DESCRIPTION OF THE DRAWINGS

The above and other characteristics and advantages of the invention will be better understood through the following illustrative and non-limitative detailed description of preferred embodiments thereof, with reference to the appended drawings, wherein:

FIG. 1 (prior art) shows the transient response of V_{DS} of a transistor, following switching from conduction to cutoff;

FIG. 2 (prior art) typical use of MOSFET transistors is for implementing a “half bridge”;

FIGS. 3A-3B show the principle of a common way to solve the voltage overshoot problem;

FIG. 3C shows another method for controlling overvoltage at turn off of transistors, when there are two transistors, an upper transistor Q1 and a lower transistor Q2;

FIG. 3D illustrates another circuitry for solving the overvoltage problem, using an inductor and a diode to reduce the energy losses;

FIG. 4 shows the impedance characteristics of a typical ferrite bead;

FIG. 5 shows an equivalent circuit of a typical ferrite bead;

FIG. 6A shows an equivalent circuit of a typical ferrite driven by a voltage source for characterization by simulation;

FIG. 6B shows simulated values of the bead total impedance, the ohmic portions and the reactive portion, as a function of frequency;

FIG. 7 illustrates a generic representation of snubber with ferrite bead discharge according to the invention for the lower switch.

FIG. 8 illustrates a generic representation of snubber with ferrite bead discharge according to the invention for the upper switch.

FIG. 9 shows an implementation of a snubber circuit using ferrite bead, according to an embodiment of the invention;

FIGS. 10a-10d show simulated results for a ferrite bead with ohmic resistance of 1 KΩ;

FIGS. 11a-11d show the same simulated results for a ferrite bead with ohmic resistance of 10 KΩ;

FIG. 12A shows a simulation model of a half-bridge without using a snubber;

FIG. 12B shows simulated results for the voltage across the transistor for the model of half bridge without using a snubber, shown in FIG. 12A;

FIG. 13A shows a simulation model of a half-bridge with an RCD (Resistor-Capacitor-Diode) snubber;

FIG. 13B shows simulated results for the voltage across the transistor for the model of half bridge with an RCD (Resistor-Capacitor-Diode) snubber, shown in FIG. 13A;

FIG. 14A shows a simulation model of a half-bridge with a snubber that uses the proposed ferrite bead which replaces the resistor, according to an embodiment of the invention;

FIG. 14B shows simulated results for the voltage across the transistor for the model of half-bridge with a snubber that uses the proposed ferrite bead, which replaces the resistor, shown in FIG. 14A; and

FIG. 15 shows a generic configuration of a snubber circuit using a ferrite bead for a half bridge configuration, according to the invention.

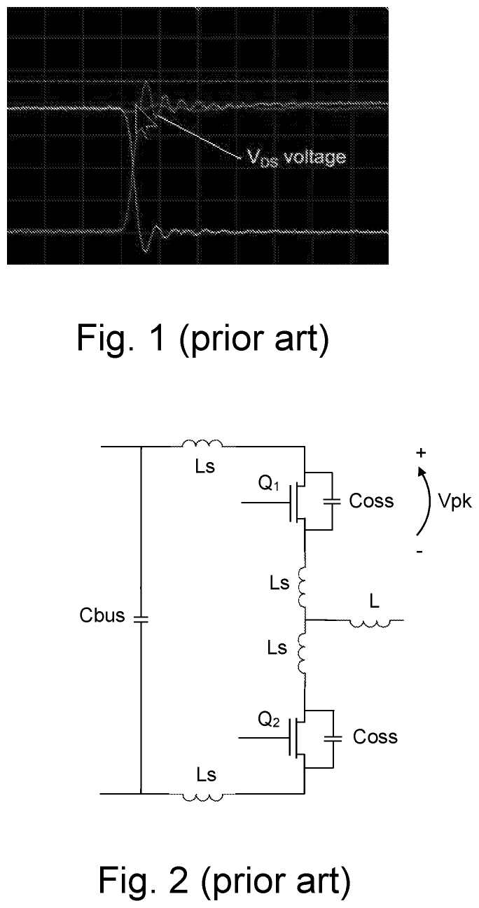

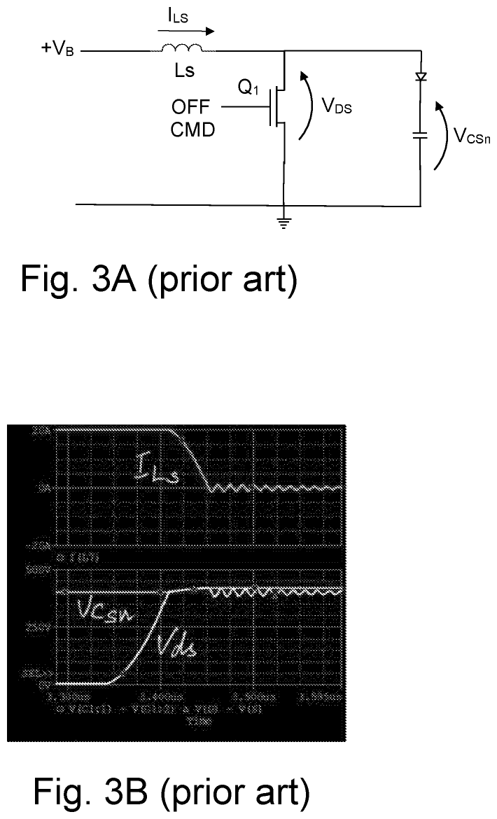

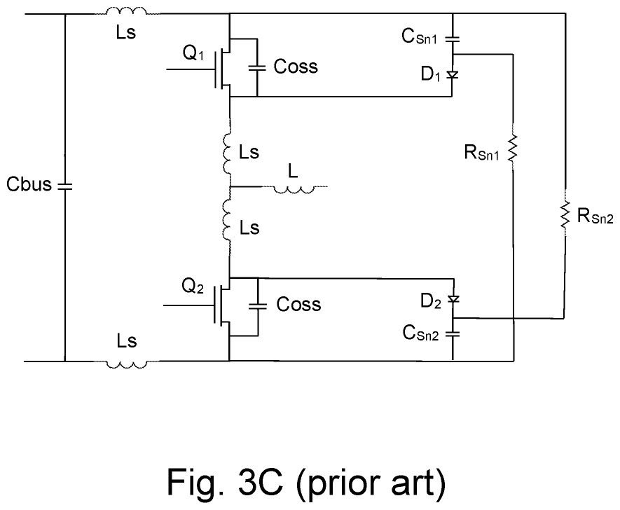

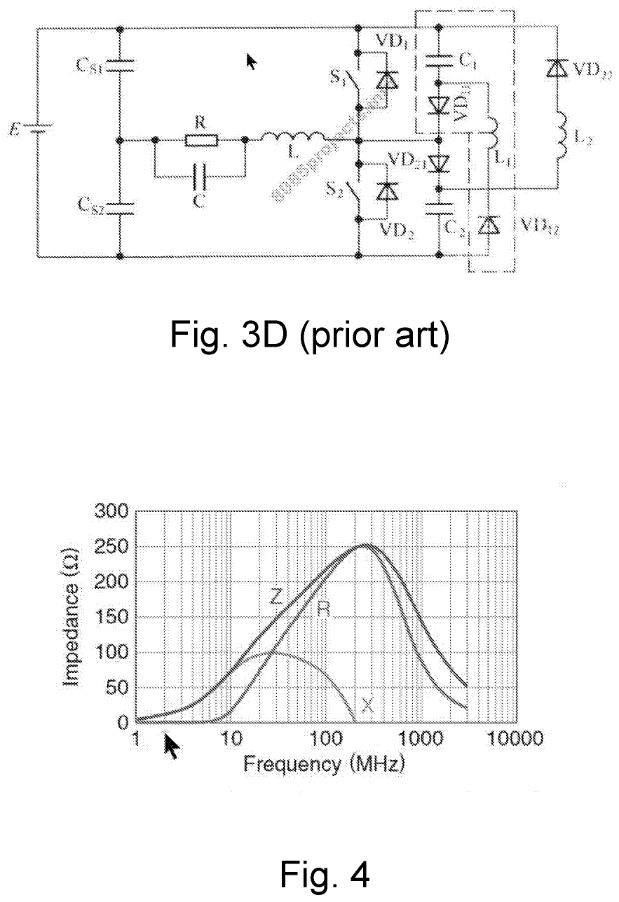

### DETAILED DESCRIPTION OF PREFERRED EMBODIMENTS

The present invention proposes a method and circuitry for protecting transistors such as GaN HEMT (Gallium Nitride High-Electron-Mobility Transistor) from overvoltage, resulting from transients that follow toggling between switching states, using a unique discharge element (a ferrite bead) with reduced energy losses (compared to the losses of a resistor as the discharge element). The ferrite bead causes the discharge current to be much more smooth and therefore, substantially reduces the ElectroMagnetic Interference (EMI).

FIG. 4 shows the impedance characteristics of such a ferrite bead. It can be seen that the general impedance Z increases with frequency, and consists of an inductive portion X and a resistive portion R, which increases with frequency. As long as the frequency is low, the impedance of this bead is low and there are almost no losses. However, when the current frequency is high (such as when pulses are uses), it introduces a combination of resistive and inductive elements. When used in a snubber circuit, the inductive part helps to smooth the discharge current while the resistive part damps the oscillations.

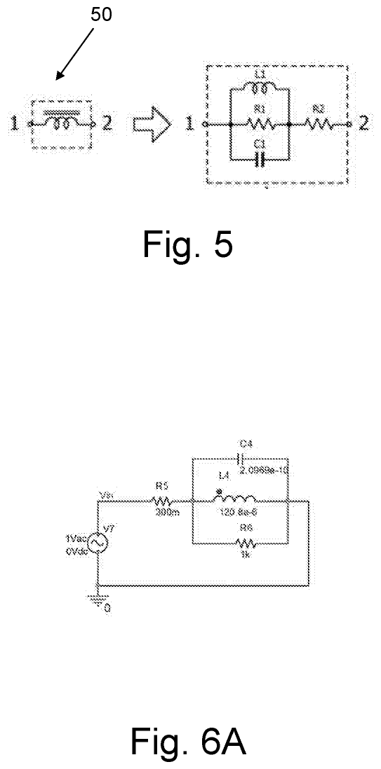

FIG. 5 shows an equivalent circuit of a typical ferrite bead 50, where R2 is the ohmic resistance of the wire used to connect the bead (very low), L1 is the inductance, R1 is the ohmic resistance and C1 is a parasitic capacitance between turns of the bead's inductance. The inductive part L1 helps forming the current to include less peaks and being smoother. The resistive part R1 serves as a damping element, for damping where oscillations that cause noise and disturbances as a result of Reversed Recovery.

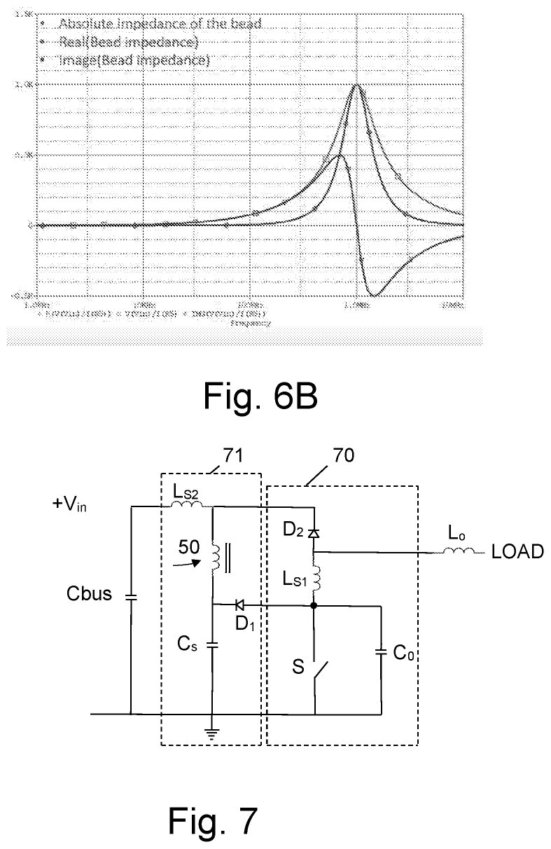

FIG. 6A shows a PSPICE simulation model of a typical ferrite bead with a resonant frequency of about 1 MHz. FIG. 6B shows simulated values of the bead total impedance (green), the ohmic portions (red) and the reactive portion (purple) as a function of frequency.

FIG. 7 shows the generic configuration of a snubber circuit using a ferrite bead 50 for a lower switch, according to an embodiment of the invention. The circuit comprises a switching cell 70 that consisting of a switch S with alternating opposite conduction states. The switch S includes an inherent output capacitance Co and is serially connected via one contact to a diode D₂. The switch (S) connects, via a first stray inductance Ls1, between a port of a power supply and an output inductor (Lo) feeding a load. Diode (D₂) connects, via a second stray inductance Ls2, between the other port of the power supply and the output inductor (Lo), such that when the switch passes from a conducting state to a non-conducting state, its inherent output capacitance Co is charged by a current pulse from the first stray inductance Ls1. A snubber circuit (71) consisting of a ferrite bead 50, a snubber capacitor (Cs) and a diode D1, connects between the other contact of the switch and the other port of the power supply, for discharging a portion of the charge across the inherent output capacitance (Co) of the switch to snubber capacitor (Cs) via the other port.

In this representation, S represents a semiconductor switch, Cₒ is the capacitance across the switch S, I_{L} represents the load current that is switched and flows via the output inductance Lo and Ls1 is a stray inductance. At turn off of the switch S, the load current is channeled to the bus by diode D₂ while the current of Ls1 is forwarded to the snubber capacitor Cs. The extra charge accumulated by Cs is discharged via the ferrite bead 50 into the bus.

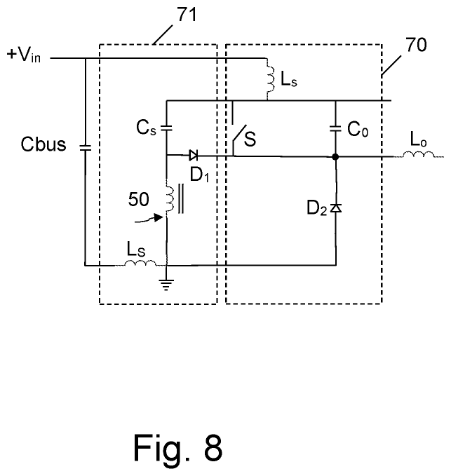

FIG. 8 shows a generic configuration of a snubber circuit using a ferrite bead for an upper switch, according to the invention. Similar to the configuration shown in FIG. 7, the ferrite bead 50 discharge the extra charge of the snubber capacitor Cs back to the bus.

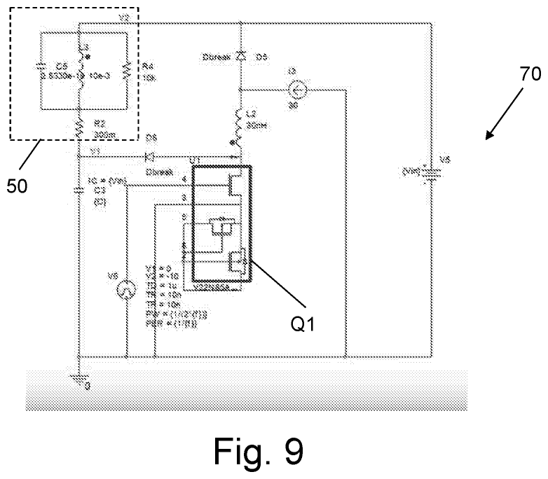

FIG. 9 shows an implementation of a snubber circuit using ferrite bead, according to another embodiment of the invention. In this example, when transistor Q1 stops conducting, capacitor C3 (which represents Csₙ) is charged via diode D6 and is then discharged via ferrite bead 50. The values of the equivalent components L3, R4, C5 and R2 of the bead were selected to be 1 mH, 10 KΩ, 0.2533 nF and 300 mΩ, respectively.

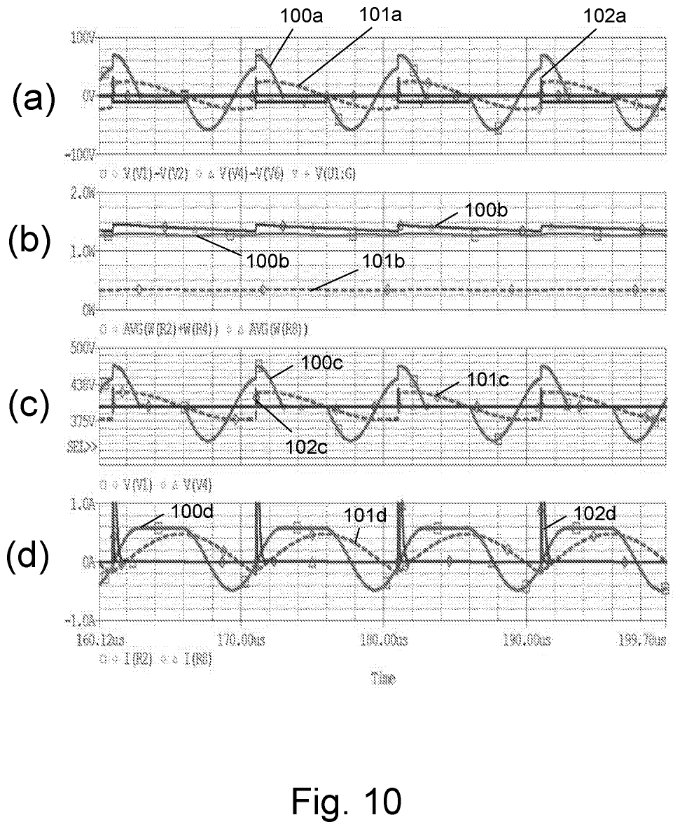

FIGS. 10a-10d show simulated results for a ferrite bead with ohmic resistance of 1 KΩ.

FIG. 10a shows simulated results of the voltage across the bead of a snubber circuit for a 10 nF capacitor (line 100a) and a 50 nF capacitor (line 101a). The voltage across the discharge resistor (line 102a) is also shown for a circuit without a bead.

FIG. 10b shows simulated results of the dissipation power across the bead of a snubber circuit for a 10 nF capacitor (line 100b) and a 50 nF capacitor (line 101b). The dissipation power (line 102b) across the discharge resistor is also shown for a circuit without a bead. It can be seen that the power loss (dissipated power) over the discharge resistor is about 1.4 W, while the power loss (dissipated power) over the ferrite bead is about 0.3 W.

FIG. 10c shows simulated results of the voltage across the bead of a snubber circuit for a 10 nF capacitor (line 100c) and a 50 nF capacitor (line 101c). The voltage across the discharge resistor is also shown (line 102c) for a circuit without a bead. It can be seen that the current flowing through a discharge resistor includes high peaks, which cause high losses (since the RMS value is proportional to the current). On the other hand, the current flowing through the ferrite bead (that replaces the discharge resistor) is relatively smooth and does not include any peaks which cause high losses.

FIG. 10d shows simulated results of the current through the bead of a snubber circuit for a 10 nF capacitor (line 100d) and a 50 nF capacitor (line 101d). The current through the discharge resistor is also shown (line 102d) for a circuit without a bead. It can be seen that the current flowing through a discharge resistor includes high peaks, which cause high losses (since the RMS value is proportional to the current).

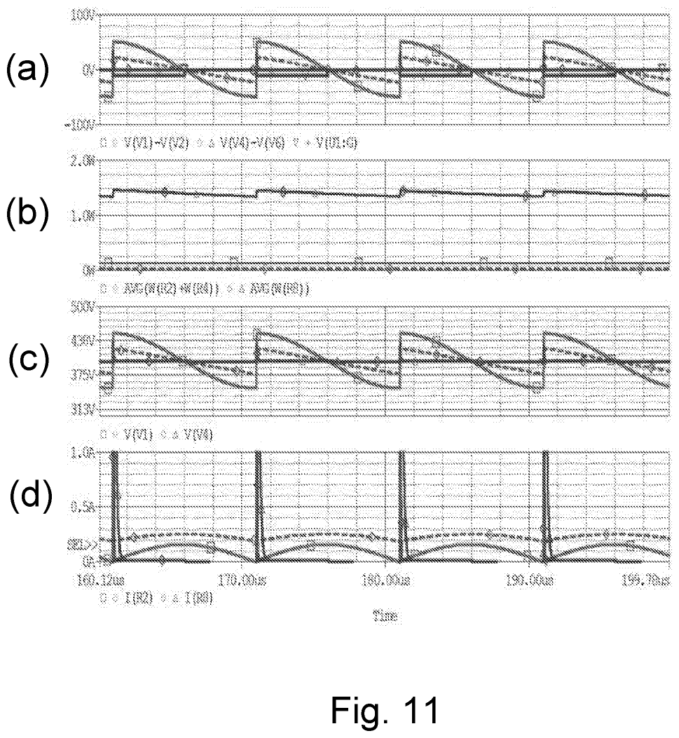

FIGS. 11a-11d show the same simulated results for a ferrite bead with ohmic resistance of 10 KΩ.

### Comparison between Circuits without a Snubber, with a Resistor Discharging Snubber and a Snubber with a Ferrite Bead Discharge

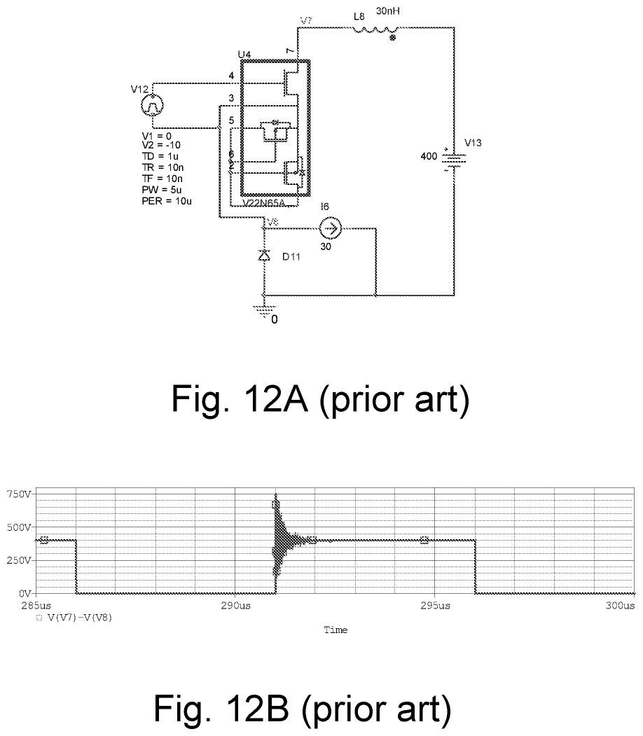

FIG. 12A shows a simulation model of a half-bridge without using a snubber. In this model, U4 represents the upper transistor Q1, L8 represents the stray inductor Ls, D11 represents the lower transistor which conducts and current source I6 represents the current of the inductor L at the moment of switching off Q1. The transistor Q1 is turned on and off by a pulse source V12.

FIG. 12B shows simulated results for the voltage across the transistor Q1 for the model of half-bridge without using a snubber, shown in FIG. 10A. In this case, it can be seen that the overshoot following switching Q1 off is very high (about 750 V while the absolute maximum rating of Vds voltage is 650 V) and will entail damage to Q1.

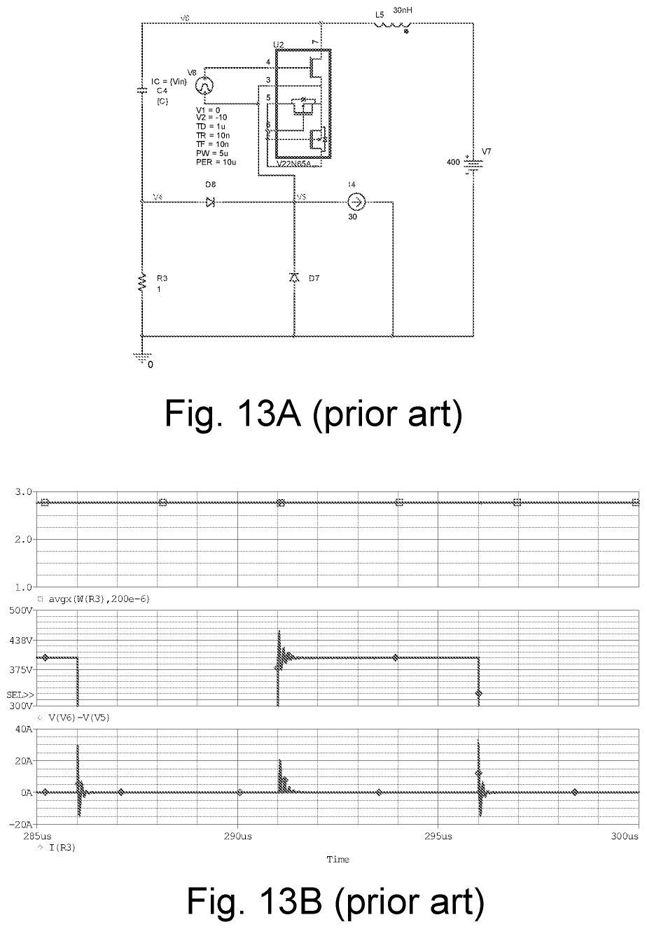

FIG. 13A shows a simulation model of a half-bridge with an RCD (Resistor-Capacitor-Diode) snubber. In this model, U2 represents the upper transistor Q1, L5 represents the stray inductor Ls, D7 represents the lower transistor which conducts and current source I4 represents the current of the inductor L at the moment of switching off Q1. The transistor Q1 is turned on and off by a pulse source V8. In this model, the output capacitance C4 of the transistor is charged by the current of L5 and discharges via resistor R3.

FIG. 13B shows simulated results for the voltage across the transistor Q1 for the model of half-bridge with an RCD (Resistor-Capacitor-Diode) snubber, shown in FIG. 11A. In this case, it can be seen that the overshoot following switching Q1 off is lower than the case when no snubber is used and reaches about 450 V. However, the power dissipation (loss) in this case will still be about 2.8 W.

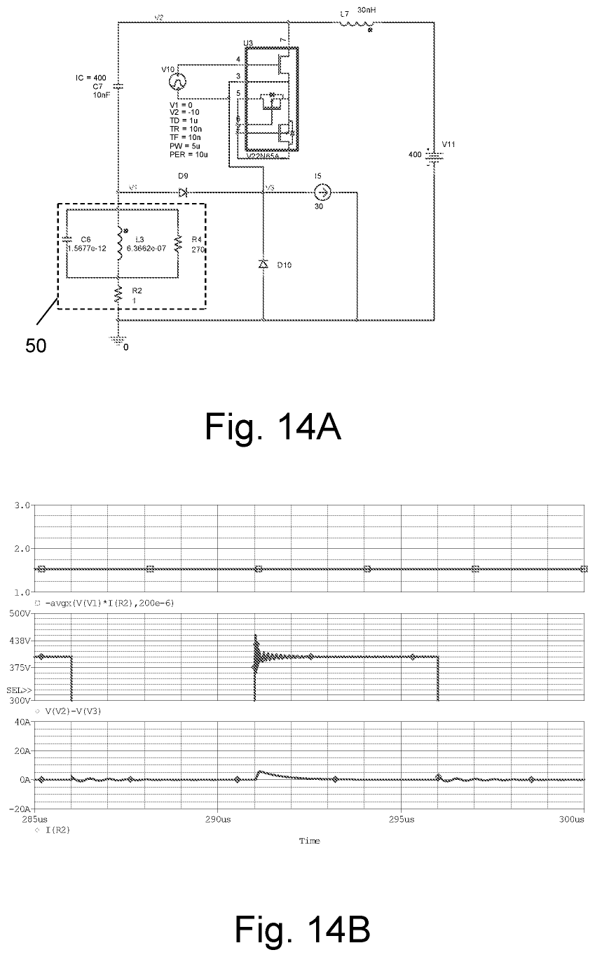

FIG. 14A shows a simulation model of a half-bridge with a snubber that uses the proposed ferrite bead (in this example, LI0805G201R-10, manufactured by Laird—Signal Integrity Products, Chattanooga, Tenn., U.S.A.), which replaces the resistor. In this model, U3 represents the upper transistor Q1, L7 represents the stray inductor Ls, D10 represents the lower transistor which conducts and current source I5 represents the current of the inductor L at the moment of switching off Q1. The transistor Q1 is turned on and off by a pulse source V10. In this model, the output capacitance C7 of the transistor is charged by the current of L7 and discharges via ferrite bead 50.

FIG. 14B shows simulated results for the voltage across the transistor Q1 for the model of half-bridge with a snubber that uses the proposed ferrite bead, which replaces the resistor, shown in FIG. 14A. In this case, it can be seen that the overshoot following switching Q1 off is lower than the case when no snubber is used, but still reaches about 450 V. However, due to the fact that the discharge current is smoothed by the ferrite bead, the power dissipation (loss) in this case will about 1.5 W, which is about half of the loss in the model of FIG. 13A.

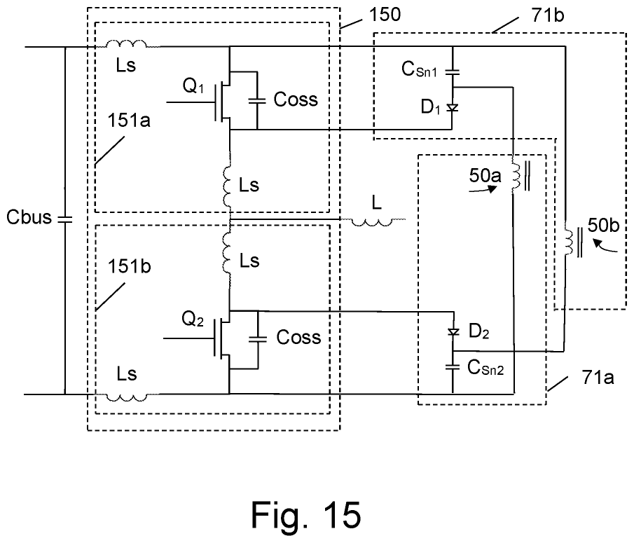

FIG. 15 shows a generic configuration of a snubber circuit using a ferrite bead for a half bridge configuration 150, according to the invention. In this example, ferrite beads 50a and 50b are used instead of resistors in snubber circuits 71a and 71b, respectively. Similar to the configurations shown in FIG. 7, and FIG. 8 the ferrite beads 50a and 50b of the lower and upper switches 151a and 151b, respectively, discharge the extra charge of the snubber capacitors Csn1 and Csn2 back to the bus.

The above examples and description have of course been provided only for the purpose of illustrations, and are not intended to limit the invention in any way. As will be appreciated by the skilled person, the invention can be carried out in a great variety of ways, for different power switched such as IGBTs, employing more than one technique from those described above, all without exceeding the scope of the invention.

1. A method for reducing the energy losses of a snubber circuit used to protect current switching devices from overvoltage, comprising:
a) providing a switching cell (70) consisting of a switch (S) with alternating opposite conduction states, said switch (S) being serially connected via one contact to a first diode (D₂), said switch (S) includes an inherent output capacitance (Co), said switch (S) connects, via a first stray inductance (Ls1), between one port of a power supply and an output inductor (Lo) feeding a load, and said first diode (D₂) connects, via a second stray inductance (Ls2), between the other port of said power supply and said output inductor (Lo), such that whenever said switch passes from a conducting state to a non-conducting state, its inherent output capacitance (Co) is charged by a current pulse from said first stray inductance (Ls1); and
b) connecting a snubber circuit (71) consisting of a ferrite bead (50), a snubber capacitor (Cs) and a second diode (D1), between the other contact of said switch and said other port, for discharging at least a portion of the charge across said inherent output capacitance (Co) of said switch to said snubber capacitor (Cs) via said other port.

2. A method according to claim 1, wherein the ferrite bead is represented by a parallel connection of a stray capacitor, a frequency-dependent inductor and a frequency-dependent resistor, said parallel connection is followed by a series constant resistance.

3. A method according to claim 1, wherein the ferrite bead smooths the discharge current of the output capacitance.

4. A method according to claim 3, wherein the peak resistance of the frequency-dependent resistor is in the range of 1 to 10 KΩ.

5. A method according to claim 1, wherein the switch is implemented by a FET transistor.

6. A method according to claim 1, wherein the switch is a power GaN transistor.

7. Circuitry for reducing the energy losses of a snubber circuit used to protect current switching devices from overvoltage, comprising:
a. a switching cell consisting of a switch with alternating opposite conduction states, said switch being serially connected via one contact to a first diode, said switch includes an inherent output capacitance, said switch connects, via a first stray inductance, between one port of a power supply and an output inductor feeding a load, and said first diode connects, via a second stray inductance, between the other port of said power supply and said output inductor, such that whenever said switch passes from a conducting state to a non-conducting state, its inherent output capacitance is charged by a current pulse from said first stray inductance; and
b. a snubber circuit consisting of a ferrite bead, a snubber capacitor and a second diode, said snubber circuit being connecting between the other contact of said switch and said other port, for discharging at least a portion of the charge across said inherent output capacitance of said switch to said snubber capacitor via said other port.

8. A half bridge circuitry for reducing the energy losses of a snubber circuit used to protect current switching devices from overvoltage, comprising:
a. a first switching cell consisting of a first switch with alternating opposite conduction states, said switch being serially connected via one contact to a first diode, said first switch includes an inherent output capacitance, said first switch connects, via a first stray inductance, between one port of a power supply and an output inductor feeding a load, and said first diode connects, via a second stray inductance, between the other port of said power supply and said output inductor, such that whenever said switch passes from a conducting state to a non-conducting state, its inherent output capacitance is charged by a current pulse from said first stray inductance;
b. a second switching cell consisting of a second switch with alternating opposite conduction states, said second switch being serially connected via one contact to a third diode, said second switch includes an inherent output capacitance, said second switch connects, via a third stray inductance, between one port of said power supply and an output inductor feeding said load, and said third diode connects, via a fourth stray inductance, between the other port of said power supply and said output inductor, such that whenever said second switch passes from a conducting state to a non-conducting state, its inherent output capacitance is charged by a current pulse from said third stray inductance;
c. a first snubber circuit consisting of a ferrite bead, a snubber capacitor and a second diode, said first snubber circuit being connecting between the other contact of said first switch and said other port, for discharging at least a portion of the charge across said inherent output capacitance of said first switch to said snubber capacitor via said other port; and
d. a second snubber circuit consisting of a ferrite bead, a snubber capacitor and a second diode, said second snubber circuit being connecting between the other contact of said second switch and said other port, for discharging at least a portion of the charge across said inherent output capacitance of said first switch to said snubber capacitor via said other port.

9. A method according to claim 8, wherein the first and second switches are FET transistors.

10. A method according to claim 8, wherein the first and second switches are GaN transistors.

11. Circuitry according to claim 7, in which the switch is implemented by a FET transistor.

12. Circuitry according to claim 7, in which the switch is a power GaN transistor.
